(19) United States
(12) Patent Application Publication
(10) Pub. No.: US 2006/0132152 A1
(43) Pub. Date: Jun. 22, 2006

(54) Contact-type film probe

(76) Inventors: Chih Yuan Wang, Shengang Township (TW); Heng Yi Chang, Taipei City (TW); Ya Ling Shu, Dacheng Township (TW); Yi Te Lee, Kaohsiung City (TW); Hui Yu Chang, Huatan Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/014,977

(22) Filed: Dec. 20, 2004

(51) Int. Cl. G01R 31/00; G01R 31/02

(52) U.S. Cl. 324/754; 324/770

(57) ABSTRACT

A contact-type film probe including a plastic substrate. Multiple signal lines are arranged on one face of the substrate. A contact conductive layer is disposed at one end of each signal line. The contact conductive layers serve to contact with the wires of the liquid crystal display. The contact conductive layers are made by means of complex electroplating to enhance anti-abrasive ability so that the using life of the contact-type film probe can be prolonged.

### BACKGROUND OF THE INVENTION

The present invention is related to a film probe for testing liquid crystal display, and more particularly to a contact-type film probe, in which the contact conductive layer is improved to enhance the anti-abrasive ability and prolong using life of the contact-type film probe.

In a conventional contact-type soft film probe structure, multiple one-to-one straight film probes are directly made on a specific tool according to the wire layout of a liquid crystal display. The probes directly contact with the wires of the liquid crystal display. After contacted, the signal will be input via the probes to activate the liquid crystal display. According to the state of display, it can be judged whether the quality of the liquid crystal display is good or bad.

FIGS. 2 and 3 show a conventional contact-type soft film probe. Multiple signal lines 82 are arranged on one face of a plastic substrate 81 according to wire layout of a liquid crystal display. A contact conductive layer 83 is disposed at one end of each signal line 82 to form a probe. The other section of the signal line 82 free from the contact conductive layer 83 is coated with an insulating layer 84.

The thickness of each layer of the film probe is in the grade of micron so that the thickness of the film probe as a whole is still very thin. Accordingly, when contacting the film probe with the wire 91 of the liquid crystal display 9 as shown in FIG. 4, it is necessary to slightly apply a pressure onto the probe, whereby the contact conductive layers 83 of the film probe can truly contact with the wires 91 of the liquid crystal display. However, the contact conductive layers 83 are generally made of copper foil material. Therefore, during contacting, the edges and corners of the wires 91 of the liquid crystal display tend to partially over-wear the contact conductive layers 83 and signal lines 82. This may cut off the contact conductive layers 83 and the signal lines 82. As a result, the signal cannot be normally transmitted to the wires of the liquid crystal display. This will make the liquid crystal display unable to display pictures or lead to poor display of the pictures. Accordingly, the test result of the liquid crystal display will be affected. Furthermore, in the case that the contact conductive layers 83 are worn out or cut off, the using life of the film probe will be shortened and the cost will be increased.

### SUMMARY OF THE INVENTION

It is therefore a primary object of the present invention to provide a contact-type film probe in which the contact conductive layers are made by means of complex electroplating to enhance anti-abrasive ability so that the using life of the contact-type film probe can be prolonged.

According to the above object, the contact-type film probe of the present invention includes a plastic substrate. Multiple signal lines are arranged on one face of the substrate. A contact conductive layer is disposed at one end of each signal line. The contact conductive layers are made by means of complex electroplating to enhance anti-abrasive ability. The other section of each signal line free from the contact conductive layer is coated with an insulating layer.

The present invention can be best understood through the following description and accompanying drawings wherein:

### BRIEF DESCRIPTION OF THE DRAWINGS

FIG. 1 is a sectional view showing the structure of the present invention;

FIG. 2 is a sectional view showing the structure of a conventional contact-type soft film probe;

FIG. 3 is a sectional view in another direction, showing the structure of the conventional contact-type soft film probe; and

FIG. 4 is a sectional view showing the use of the conventional contact-type soft film probe.

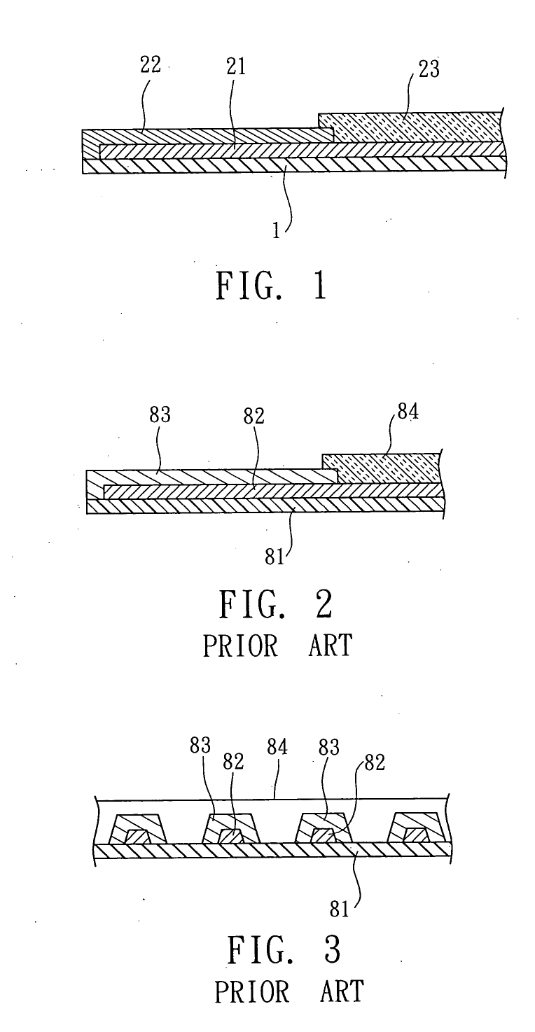

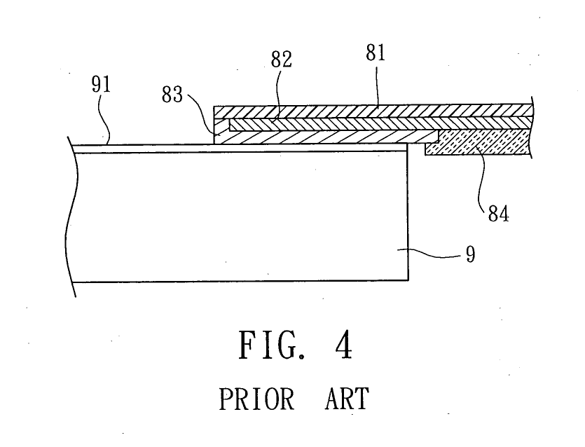

### DETAILED DESCRIPTION OF THE PREFERRED EMBODIMENT

Please refer to FIG. 1. The contact-type film probe of the present invention includes a plastic substrate 1. Multiple signal lines 21 are arranged on one face of the substrate 1. A contact conductive layer 22 is disposed at one end of each signal line 21. The contact conductive layer 22 is made by means of complex electroplating to enhance anti-abrasive ability. The contact conductive layer 22 serves to contact with the wire of the liquid crystal display. The other section of each signal line 21 free from the contact conductive layer 22 is coated with an insulating layer 23.

The substrate 1 can be made of any of polyimide, PET, PC, PMMA and polysulfone. The conductive layer can be made of any of gold, silver, copper, nickel, chromium and aluminum.

Importantly, the contact conductive layer 22 made by means of complex electroplating can be made of any of complex metal materials such as nickel-chromium, nickel-cobalt, nickel-phosphorus, iron-tungsten, iron-tungsten-nickel, nickel-cobalt-iron and nickel-chromium-iron.

The contact conductive layers 22 are made by means of complex electroplating so that the anti-abrasive ability of the contact conductive layers 22 is enhanced relative to the copper-made contact conductive layers of the prior art. Accordingly, when contacting with the edges or corners of the wires of the liquid crystal display, the wear of the contact conductive layers 22 is greatly reduced. Therefore, the contact conductive layers 22 and the signal lines 21 are uneasy to be worn off.

The above embodiment is only used to illustrate the present invention, not intended to limit the scope thereof. Many modifications of the above embodiment can be made without departing from the spirit of the present invention.

What is claimed is:

1. A contact-type film probe comprising a plastic substrate, multiple signal lines being arranged on one face of the substrate, a contact conductive layer being disposed at one end of each signal line, the contact conductive layer being made by means of complex electroplating to enhance anti-abrasive ability, the other section of each signal line free from the contact conductive layer being coated with an insulating layer.

2. The contact-type film probe as claimed in claim 1, wherein the substrate is made of any of polyimide, PET, PC, PMMA and polysulfone.

3. The contact-type film probe as claimed in claim 1, wherein the conductive layer is made of any of gold, silver, copper, nickel, chromium and aluminum.

4. The contact-type film probe as claimed in claim 1, wherein the contact conductive layer is made of any of complex metal materials such as nickel-chromium, nickel-cobalt, nickel-phosphorus, iron-tungsten, iron-tungsten-nickel, nickel-cobalt-iron and nickel-chromium-iron.
